(19) United States
(12) Patent Application Publication
(10) Pub. No.: US 2025/0216768 A1
(43) Pub. Date: Jul. 3, 2025

(54) BLANK MASK AND METHOD OF FABRICATING THE SAME

(71) Applicant: SK enpulse Co., Ltd., Gyeonggi-do (KR)

(72) Inventors: Gyeongse JEONG, Seoul (KR); Haeyoung JEONG, Seoul (KR); Hyung Joo LEE, Seoul (KR); Soyeong CHOI, Seoul (KR)

(21) Appl. No.: 19/001,570

(22) Filed: Dec. 26, 2024

(30) Foreign Application Priority Data
Dec. 29, 2023 (KR) 10-2023-0197826
Dec. 29, 2023 (KR) 10-2023-0197827

(51) Int. Cl. G03F 1/48; G03F 1/26; G03F 1/84

(52) U.S. Cl. CPC G03F 1/48; G03F 1/84; G03F 1/26

(57) ABSTRACT

Provided is a blank mask, including an optical substrate including a light-transmitting substrate and a light-shielding film disposed on the light-transmitting substrate, and a photoresist layer disposed on the optical substrate. The photoresist layer includes 49 regions that are divided into 7 regions arranged at regular intervals in a horizontal direction and 7 regions arranged at regular intervals in a vertical direction, wherein the 49 regions include a first region corresponding to a center of the optical substrate; second regions arranged along a periphery of the first region; third regions arranged along a periphery of the second regions; and fourth regions corresponding to an outer edge of the optical substrate, wherein a density of optical irregularities in the fourth regions is greater than a density of optical irregularities in the first region, the second regions and the third regions.

### CROSS-REFERENCES TO RELATED APPLICATION

The present application claims priority under 35 U.S.C. § 119(a) to Korean Patent Application Number 10-2023-0197827, filed on Dec. 29, 2023, and to Korean Patent Application Number 10-2023-0197826, filed on Dec. 29, 2023, which are both incorporated herein by reference in their entirety.

### TECHNICAL FIELD

Embodiments of the present disclosure relate generally to semiconductor technology and in particular to a blank mask and a method of fabricating the same.

### BACKGROUND ART

Due to the high integration of semiconductor devices, etc., there is a demand for the refinement of circuit patterns of semiconductor devices. Thereby, the importance of lithography technology, a technology that develops circuit patterns on the surface of a wafer using a photomask, is attracting more attention.

To develop refined circuit patterns, a shorter wavelength of an exposure light source used in an exposure process is required. As examples of exposure light sources recently used, there are ArF excimer laser (wavelength: 193 nm), and the like.

Further, examples of a photomask include a binary mask, a phase shift mask, and the like.

A binary mask has a configuration wherein a light-shielding layer pattern is formed on a light-transmissive substrate. On the surface of a binary mask, where patterns are formed, a light transmission part excluding a light-shielding layer transmits exposure light, and a light-shielding part including a light-shielding layer blocks exposure light, exposing a pattern on a resist film of a wafer surface. Problems may occur in the fine pattern phenomenon due to light diffraction that occurs at the edges of the light transmission part during the exposure process as the pattern of a binary mask becomes finer.

Well-known examples of phase shift masks are the Levenson-type mask, the outrigger-type mask, and the half-tone-type mask. Among these masks, the half-tone-type phase shift mask has a pattern, which is made of a semi-transmissive film, formed on a light-transmissive substrate 10. On the patterned surface of the half-tone-type phase shift mask, a light transmission part excluding a semi-transmissive layer transmits exposure light, and a semi-transmissive part including a semi-transmissive layer transmits attenuated exposure light. The attenuated exposure light has a phase difference compared to the exposure light that has passed through the light transmission part. Accordingly, diffracted light occurring at the edge of the light transmission part is canceled out by exposure light that has been transmitted through the semi-transmissive part, so that the phase shift mask can form a more elaborate fine pattern on a wafer surface.

### SUMMARY

Therefore, the embodiments of the present disclosure have been made in view of the above problems, and the embodiments provide a blank mask that is precisely patterned to provide a photomask having low optical distortion; and a method of fabricating the blank mask.

In accordance with an embodiment of the present disclosure, provided is a blank mask, including an optical substrate including a light-transmitting substrate and a light-shielding film disposed on the light-transmitting substrate; and a photoresist layer disposed on the optical substrate, wherein the photoresist layer includes 49 regions that are divided into 7 regions arranged at regular intervals in a horizontal direction and 7 regions arranged at regular intervals in a vertical direction, and a thickness variation in the 49 regions is less than 100 Å.

In the blank mask according to an embodiment, the 49 regions may include a first region corresponding to a center of the optical substrate; second regions arranged along a periphery of the first region; third regions arranged along the periphery of the second regions; and fourth regions corresponding to an outer edge of the optical substrate, wherein an average thickness of the fourth regions is thicker than an average thickness of the third regions.

In the blank mask according to an embodiment, the average thickness of the fourth regions may be about 3 Å to about 10 Å thicker than the average thickness of the third regions.

In the blank mask according to an embodiment, the average thickness of the fourth regions may be thicker than an average thickness of the second regions.

In the blank mask according to an embodiment, an average thickness of the first region may be thicker than the average thickness of the second regions.

In the blank mask according to an embodiment, the average thickness of the first region may be thicker than the average thickness of the third regions.

In accordance with another embodiment of the present disclosure, there is provided a method of fabricating the blank mask, the method including forming an optical substrate that includes a light-shielding film disposed on a transparent substrate; and forming a photoresist layer on the light-shielding film while rotating the optical substrate, wherein forming the photoresist layer includes performing first rotation for the optical substrate; performing second rotation for the optical substrate at a speed faster than the first rotation; performing third rotation for the optical substrate at a speed faster than the second rotation; performing fourth rotation for the optical substrate at a speed faster than third rotation; performing fifth rotation for the optical substrate at a slower speed than the fourth rotation; and performing sixth rotation for the optical substrate at a slower speed than the fifth rotation.

In the method of fabricating a blank mask according to an embodiment, the first rotation speed may be 30 rpm to 70 rpm, the second rotation speed may be 50 rpm to 100 rpm, the third rotation speed may be 100 rpm to 150 rpm, the fourth rotation speed may be 800 rpm to 3000 rpm, the fifth rotation speed may be 500 rpm to 2500 rpm, and the sixth rotation speed may be 100 rpm to 500 rpm.

In the method of fabricating a blank mask according to an embodiment, the first rotation operation, the second rotation operation, the third rotation operation, the fourth rotation operation, the fifth rotation operation and the sixth rotation operation may be performed at 20° C. to 30° C.

In the method of fabricating a blank mask according to an embodiment, the fourth rotation operation may be performed for 0.5 sec to 2 sec.

The blank mask according to an embodiment may include an optical substrate including a light-transmitting substrate and a light-shielding film disposed on the light-transmitting substrate; and a photoresist layer disposed on the optical substrate, wherein the photoresist layer includes 49 regions that are divided into 7 regions arranged at regular intervals in a horizontal direction and 7 regions arranged at regular intervals in a vertical direction, wherein the 49 regions include a first region corresponding to the center of the optical substrate; second regions arranged along the periphery of the first region; third regions arranged along the periphery of the second regions; and fourth regions corresponding to the outer edge of the optical substrate, wherein the density of optical irregularities in the fourth regions is higher than the density of optical irregularities in the first region, the second regions and the third regions.

In the blank mask according to an embodiment, the optical irregularities may be detected by a 532 nm laser, and may be arranged in a number of less than 30/36 inches² on the light-shielding film.

In the blank mask according to an embodiment, the density of optical irregularities in the fourth region may be 15/36 inches² to 25/36 inches².

In the blank mask according to an embodiment, the density of optical irregularities in the first region, the second region and the third region may be 5/36 inches² to 20/36 inches².

In the blank mask according to an embodiment, the diameter of the optical irregularities may be 10 nm to 500 nm.

In the blank mask according to an embodiment, a difference between the density of optical irregularities in the fourth region and the density of optical irregularities in the first region, the second region and the third region may be 1/36 inches² to 15/36 inches².

In the blank mask according to an embodiment, in each of the fourth regions, the number of optical irregularities may be 3 or less.

In the blank mask according to an embodiment, the photoresist layer may include a flat portion disposed on the light transmission part, and the optical irregularities may have optical thicknesses different from the light transmission part.

In the blank mask according to an embodiment, the optical irregularities may include an optical path-changing part.

In the blank mask according to an embodiment, the optical path-changing part may have a refractive index different from the flat portion.

In accordance with still another embodiment of the present disclosure, there is provided a method of fabricating a semiconductor device, the method including preparing a blank mask including an optical substrate and a photoresist layer disposed on the optical substrate; forming a photomask using the blank mask; and patterning a semiconductor substrate using the photomask, wherein the optical substrate includes a light-transmitting substrate and a light-shielding film disposed on the light-transmitting substrate, the photoresist layer includes 49 regions that are divided into 7 regions arranged at regular intervals in a horizontal direction and 7 regions arranged at regular intervals in a vertical direction, wherein the 49 regions include a first region corresponding to the center of the optical substrate; second regions arranged along the periphery of the first region; third regions arranged along the periphery of the second regions; and fourth regions corresponding to the outer edge of the optical substrate, wherein the density of optical irregularities in the fourth regions is greater than the density of optical irregularities in the first region, the second regions and the third regions.

In accordance with still another embodiment of the present disclosure, there is provided a blank mask, including a light-transmissive substrate; a light-shielding film disposed on the light-transmissive substrate; and a photoresist layer disposed on the light-shielding film, wherein the photoresist layer includes 49 regions that are divided into 7 regions arranged at regular intervals in a horizontal direction and 7 regions arranged at regular intervals in a vertical direction, wherein a thickness variation in the 49 regions is less than 100 Å.

In the blank mask according to an embodiment, the 49 regions may include a first region corresponding to the center of the optical substrate; second regions arranged along the periphery of the first region; third regions arranged along the periphery of the second regions; and fourth regions corresponding to the outer edge of the optical substrate, wherein the average thickness of the fourth regions is thicker than the average thickness of the third regions.

In the blank mask according to an embodiment, the average thickness of the fourth regions may be about 3 Å to about 10 Å thicker than the average thickness of the third regions.

In the blank mask according to an embodiment, the average thickness of the fourth regions may be thicker than an average thickness of the second regions.

In the blank mask according to an embodiment, an average thickness of the first region may be thicker than the average thickness of the second regions.

In the blank mask according to an embodiment, the average thickness of the first region may be thicker than the average thickness of the third regions.

In accordance with yet another embodiment of the present disclosure, there is provided a method of fabricating the blank mask, the method including forming an optical substrate that includes a light-shielding film disposed on a transparent substrate; and forming a photoresist layer on the light-shielding film while rotating the optical substrate, wherein forming the photoresist layer includes performing first rotation for the optical substrate; performing second rotation for the optical substrate at a speed faster than the first rotation; performing third rotation for the optical substrate at a speed faster than the second rotation; performing fourth rotation for the optical substrate at a speed faster than third rotation; performing fifth rotation for the optical substrate at a slower speed than the fourth rotation; and performing sixth rotation for the optical substrate at a slower speed than the fifth rotation.

In the method of fabricating a blank mask according to an embodiment, the first rotation speed may be 30 rpm to 70 rpm, the second rotation speed may be 50 rpm to 100 rpm, the third rotation speed may be 70 rpm to 150 rpm, the fourth rotation speed may be 800 rpm to 3000 rpm, the fifth rotation speed may be 500 rpm to 2500 rpm, and the sixth rotation speed may be 100 rpm to 500 rpm.

In the method of fabricating a blank mask according to an embodiment, the first rotation operation, the second rotation operation, the third rotation operation, the fourth rotation operation, the fifth rotation operation and the sixth rotation operation may be performed at 20° C. to 30° C.

In the method of fabricating a blank mask according to an embodiment, the fourth rotation operation may be performed for 0.5 sec to 2 sec.

### Advantageous Effects

A blank mask according to an embodiment can include the photoresist layer having a high thickness uniformity overall. Accordingly, the photoresist layer can be precisely patterned in the exposure and development process. Accordingly, the blank mask according to an embodiment can precisely pattern the light-shielding film and provide a precise photomask.

In particular, in the blank mask according to an embodiment, the photoresist layer can have an outer edge region that is relatively thicker. That is, the process conditions are controlled such that the outer edge region of the photoresist layer is formed to be relatively slightly thicker, so that the photoresist layer can have a uniform thickness overall.

In addition, the process of forming the photoresist layer can include first to sixth rotation operations. Accordingly, the photoresist layer can have a uniform thickness overall. In addition, since the photoresist layer is formed by the above-described process, it can have an outer edge region that is relatively slightly thicker.

In addition, the photoresist layer can include optical irregularities. In particular, the photoresist layer can be formed such that its outer edge region has a higher optical density. Accordingly, the photoresist layer can reduce the number of optical irregularities overall.

In particular, the blank mask according to an embodiment can include the optical irregularities in a number of less than 30/36 inches².

A method of fabricating the blank mask according to an embodiment can implement the photoresist layer having optical flatness overall. Accordingly, the photoresist layer can precisely pattern the light-shielding film.

In particular, since the photoresist layer has optical irregularities, detected by the 532 nm laser, in the above-mentioned number as described above, it can be precisely developed by ultraviolet rays.

Accordingly, the blank mask according to an embodiment can provide a photomask having a precise pattern.

In particular, in the blank mask according to an embodiment, the photoresist layer can have an outer edge region that is a relatively thicker. That is, the photoresist layer can have a uniform thickness overall by controlling the process conditions such that the photoresist layer has an outer edge region that is relatively slightly thicker.

In addition, the process of forming the photoresist layer can include first to sixth rotation operations. Accordingly, the photoresist layer can have a uniform thickness overall. In addition, since the photoresist layer is formed in the above-described process, it can have an outer edge region that is relatively slightly thicker.

In addition, the photoresist layer can include optical irregularities. In particular, the outer edge region of the photoresist layer can be formed to have a higher optical density. Accordingly, the photoresist layer can reduce the number of optical irregularities overall.

In particular, the blank mask according to an embodiment can include the optical irregularities in a number of less than 30/36 inches².

The method of fabricating a blank mask according to an embodiment can implement a photoresist layer having optical flatness overall. Accordingly, the photoresist layer can precisely pattern the light-shielding film.

In particular, since the photoresist layer has the above-mentioned number of optical irregularities, detected by a 532 nm laser, as described above, it can be precisely developed by ultraviolet rays.

Therefore, the blank mask according to an embodiment can implement a photomask having a precise pattern. These and other features and advantages of the embodiments of the present disclosure will become apparent to those with ordinary skill in the art from the following detailed description of embodiments and the accompanying drawings.

### BRIEF DESCRIPTION OF THE DRAWINGS

FIG. 1 is a sectional view illustrating the cross-section of an optical substrate according to an embodiment of the present disclosure.

FIG. 2 is a sectional view illustrating the cross-section of an optical substrate according to another embodiment of the present disclosure.

FIG. 3 is a sectional view illustrating the cross-section of an optical substrate according to still another embodiment of the present disclosure.

FIG. 4 illustrates the schematic diagram of an apparatus for fabricating a blank mask according to an embodiment of the present disclosure.

FIG. 5 is a sectional view illustrating the cross-section of a blank mask according to an embodiment of the present disclosure.

FIG. 6 is a sectional view illustrating an enlarged cross-section of the blank mask according to an embodiment of the present disclosure.

FIG. 7 illustrates the plan view of a photoresist layer divided into 49 regions.

FIG. 8 is a sectional view illustrating the cross-section of a photomask according to an embodiment of the present disclosure.

### DETAILED DESCRIPTION

Hereinafter, various embodiments of the present disclosure will be described in detail such that those skilled in the art can easily implement them. However, the embodiments may be implemented in various different forms and are not limited to embodiments described herein.

The terms “about,” “substantially,” and the like used in this specification are used to mean at or close to a presented numerical value when manufacturing and material tolerances inherent in stated meaning are presented, and are used to aid understanding of the embodiments.

Throughout this specification, the term “a combination thereof” included in the Markush format expression refers to a mixture or combination of one or more elements selected from the group consisting of components described in the Markush format expression, and to include one or more selected from the group consisting of the components.

Throughout this specification, the expression “A and/or B” means “A, B, or A and B”.

Throughout this specification, terms such as “first”, “second” or “A” and “B” are used to distinguish the same terms from each other unless otherwise specified.

In this specification, “B is located on A” means “B is located on A” or “B is located on A with another layer located therebetween”, and is not interpreted as limited to B being positioned in contact with the surface of A.

In this specification, singular expressions are interpreted to include singular or plural as interpreted in context, unless otherwise specified.

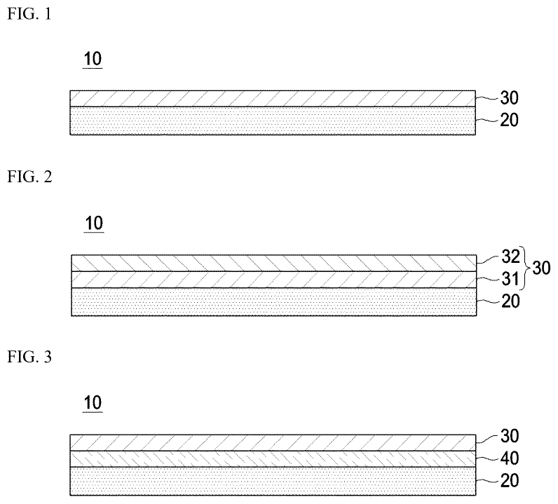

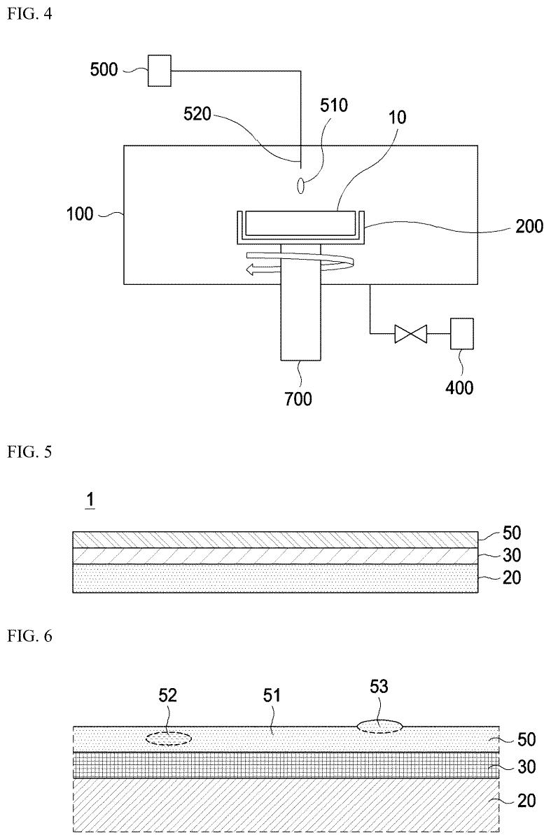

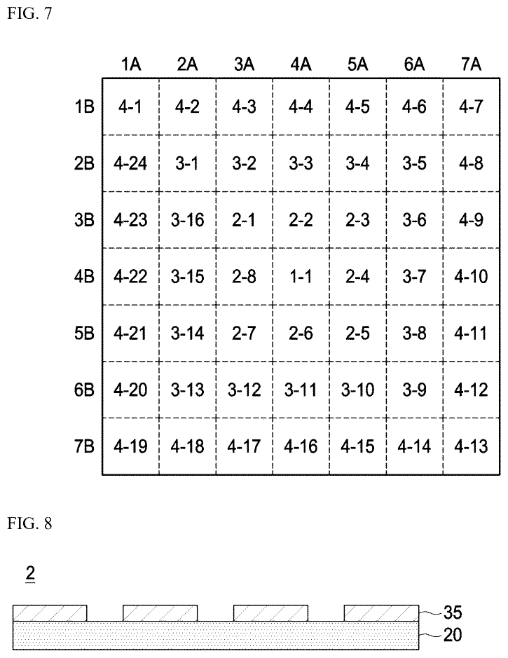

FIG. 1 is a sectional view illustrating the cross-section of an optical substrate according to an embodiment of the present disclosure. FIG. 2 is a sectional view illustrating the cross-section of an optical substrate according to another embodiment of the present disclosure. FIG. 3 is a sectional view illustrating the cross-section of an optical substrate according to still another embodiment of the present disclosure. FIG. 4 illustrates the schematic diagram of an apparatus for fabricating a blank mask according to an embodiment of the present disclosure. FIG. 5 is a sectional view illustrating the cross-section of a blank mask according to an embodiment of the present disclosure. FIG. 6 is a sectional view illustrating an enlarged cross-section of the blank mask according to an embodiment of the present disclosure. FIG. 7 illustrates the plan view of a photoresist layer divided into 49 regions. FIG. 8 is a sectional view illustrating the cross-section of a photomask according to an embodiment of the present disclosure.

The blank mask according to an embodiment may be manufactured by the following fabrication process.

First, an optical substrate 10 may be provided, as shown in FIGS. 1 to 3. The optical substrate 10 includes a light-transmissive substrate 20, and a light-shielding film 30 disposed on the light-transmissive substrate 20. In an embodiment, the light-shielding film 30 may be disposed on the light-transmissive substrate 20 to be in direct contact with the light-transmissive substrate 20.

The light-transmissive substrate 20 may have optical transparency to exposure light. For example, the light-transmissive substrate 20 may have a transmittance of greater than about 85% for exposure light having a wavelength of about 193 nm. The transmittance of the light-transmissive substrate 20 may be greater than about 87%. The transmittance of the light-transmissive substrate 20 may be less than 99.99%. Any suitable material may be used for the light-transmissive substrate 20. In an embodiment, the light-transmissive substrate 20 may include a synthetic quartz substrate. In this case, the light-transmissive substrate 20 may suppress the attenuation of transmitted light.

Since the light-transmissive substrate 20 has surface characteristics such as appropriate flatness and appropriate illuminance, it may suppress distortion of transmitted light.

The light-shielding film 30 may be disposed on a top side of the light-transmissive substrate 20.

The light-shielding film 30 may at least selectively block exposure light incident on a bottom side of the light-transmissive substrate 20.

In an embodiment as illustrated in FIG. 3, a phase shift film 40, etc. may be disposed between the light-transmissive substrate 20 and the light-shielding film 30. In such an embodiment, i.e., when a phase shift film 40 is disposed between the light-transmissive substrate 20 and the light-shielding film 30, the light-shielding film 30 may be used as an etching mask in a process of etching the phase inversion film 40, according to a pattern shape.

The light-shielding film 30 may include a transition metal and at least one of oxygen and nitrogen.

The light-shielding film 30 may include chromium, oxygen, nitrogen and carbon. The content of each element in the entire light-shielding film 30 may vary in the thickness direction. The content of each element in the entire light-shielding film 30 may differ by layer in the case of a multi-layered light-shielding film 30.

The light-shielding film 30 may include chromium in a content of about 44 atom % to about 60 atom %. The light-shielding film 30 may include chromium in a content of about 47 atom % to about 57 atom %.

The light-shielding film 30 may include carbon in a content of about 5 atom % to 30 atom %. The light-shielding film 30 may include carbon in a content of about 7 atom % to about 25% atom %.

The light-shielding film 30 may include nitrogen in a content of about 3 atom % to about 20 atom %. The light-shielding film 30 may include nitrogen in a content of about 5 atom % to about 15 atom %.

The light-shielding film 30 may include oxygen in a content of about 20 atom % to about 45 atom %. The light-shielding film 30 may include oxygen in a content of about 25 atom % to about 40 atom %.

In this case, the light-shielding film 30 may have sufficient extinction properties.

As shown in FIG. 2, the light-shielding film 30 may include a first light-shielding layer 31, and a second light-shielding layer 32 disposed on the first light-shielding layer 31.

The second light-shielding layer 32 includes a transition metal. In addition, the second light-shielding layer 32 may include at least one of oxygen, nitrogen and carbon. The second light-shielding layer 32 may include a transition metal in a content of about 50 atom % to about 80 atom %. The second light-shielding layer 32 may include a transition metal in a content of about 55 atom % to about 75 atom %. The second light-shielding layer 32 may include a transition metal in a content of about 60 atom % to about 70 atom %.

In the second light-shielding layer 32, the content of an element corresponding to at least one of oxygen, nitrogen and carbon may be about 10 atom % to about 35 atom %. In the second light-shielding layer 32, the content of an element corresponding to at least one of oxygen, nitrogen and carbon may be about 15 atom % to about 25 atom %.

The second light-shielding layer 32 may include nitrogen in a content of about 5 atom % to about 20 atom %. The second light-shielding layer 32 may include nitrogen in a content of about 7 atom % to about 13 atom %.

The second light-shielding layer 32 may include oxygen in a content of about 5 atom % to about 20 atom %. The second light-shielding layer 32 may include oxygen in a content of about 7 atom % to about 13 atom %.

The second light-shielding layer 32 may include carbon in a content of about 2 atom % to about 10 atom %. The second light-shielding layer 32 may include nitrogen in a content of about 3 atom % to about 8 atom %.

The second light-shielding layer 32 may include all of nitrogen, oxygen and carbon.

In this case, the light-shielding film 30 may form a laminate with the phase shift film 40 to help substantially block exposure light.

The first light-shielding layer 31 may include a transition metal. The first light-shielding layer 31 may include oxygen and nitrogen. The first light-shielding layer 31 may include a transition metal in a content of 30 atom % or more and 60 atom % or less. The light-shielding layer 31 may include a transition metal in a content of 35 atom % or more and 55 atom % or less. The first light-shielding layer 31 may include a transition metal in a content of 40 atom % or more and 50 atom % or less.

The sum of the oxygen content and nitrogen content in the first light-shielding layer 31 may be 40 atom % or more and 70 atom % or less. The sum of the oxygen content and nitrogen content in the first light-shielding layer 31 may be 45 atom % or more and 65 atom % or less. The sum of the oxygen content and nitrogen content in the first light-shielding layer 31 may be 50 atom % or more and 60 atom % or less.

The first light-shielding layer 31 may include oxygen in a content of 20 atom % or more and 40 atom % or less. The first light-shielding layer 31 may include oxygen in a content of 23 atom % or more and 33 atom % or less. The first light-shielding layer 31 may include oxygen in a content of 25 atom % or more and 30 atom % or less.

The first light-shielding layer 31 may include nitrogen in a content of 5 atom % or more and 20 atom % or less. The first light-shielding layer 31 may include nitrogen in a content of 7 atom % or more and 17 atom % or less. The first light-shielding layer 31 may include nitrogen in a content of 10 atom % or more and 15 atom % or less.

In this case, the first light-shielding layer 31 can help the light-shielding film 30 have excellent extinction properties.

The transition metal may include at least one of Cr, Ta, Ti and Hf. The transition metal may be Cr.

The thickness of the first light-shielding layer 31 may be about 250 Å to about 650 Å. The thickness of the first light-shielding layer 31 may be about 350 Å to about 600 Å. The thickness of the first light-shielding layer 31 may be about 400 Å to about 550 Å. Within the above range, the first light-shielding layer 31 may help the light-shielding film 30 effectively block exposure light.

The thickness of the second light-shielding layer 32 may be about 30 Å to about 200 Å. The thickness of the second light-shielding layer 32 may be about 30 Å or more and about 100 Å. The thickness of the second light-shielding layer 32 may be about 40 Å to about 80 Å. Within the above range, the second light-shielding layer 32 may improve the extinction characteristics of the light-shielding film 30 and may help to more precisely control the side surface profile of a light-shielding pattern film 35 formed during the patterning of the light-shielding film 30.

A ratio of the thickness of the second light-shielding layer 32 to the thickness of the first light-shielding layer 31 may be about 0.05 to about 0.3. The ratio of the thickness of the second light-shielding layer 32 to the thickness of the first light-shielding layer 31 may be about 0.07 to about 0.25. The ratio of the thickness of the second light-shielding layer 32 to the thickness of the first light-shielding layer 31 may be about 0.1 to about 0.2.

In this case, the light-shielding film 30 has sufficient extinction characteristics and may more precisely control the side surface profile of a light-shielding pattern film 35 formed during the patterning of the light-shielding film 30.

The content of a transition metal in the second light-shielding layer 32 may be larger than the content of a transition metal in the first light-shielding layer 31.

To more precisely control the side surface profile of the light-shielding pattern film 35 formed by patterning the light-shielding film 30 and to ensure that the reflectance of the surface of the light-shielding film 30 for inspection light in defect inspection has a value suitable for inspection, the second light-shielding layer 32 may be required to have a larger transition metal content than the first light-shielding layer 31.

In this case, recovery, recrystallization, and grain growth may occur in a transition metal contained in the second light-shielding layer 32 during the heat treatment of the formed light-shielding film 30. If grain growth occurs in the second light-shielding layer 32 containing a high content of a transition metal, the illuminance characteristics of the surface of the light-shielding film 30 may excessively change due to excessively grown transition metal particles. This may cause an increase in the number of pseudo defects detected when defects on the surface of the light-shielding film 30 are inspected with high sensitivity.

The light-shielding film 30, may have a transmittance of about 1% to about 2% for light with a wavelength of 193 nm. The light-shielding film 30 may have a transmittance of about 1.3% to about 2% for light with a wavelength of 193 nm. The light-shielding film 30 may have a transmittance of about 1.4% to about 2% for light with a wavelength of 193 nm.

The light-shielding film 30 may have an optical density of about 1.8 to about 3. The light-shielding film 30 may have an optical density of about 1.9 to about 3. By keeping the optical density within the above ranges, a thin film containing the light-shielding film 30 may effectively suppress the transmission of exposure light.

As shown in FIG. 3, the optical substrate 10 may further include a phase shift film 40.

The phase shift film 40 may be disposed between the light-transmissive substrate 20 and the light-shielding film 30. The phase shift film 40 may be a thin film that attenuates the light intensity of penetrating exposure light and adjusts a phase difference to substantially suppress the diffracted light occurring at the edge of a pattern.

The phase shift film 40 may have a phase difference of about 170° to about 190° for light with a wavelength of 193 nm. The phase shift film 40 may have a phase difference of about 175° to about 185° for light with a wavelength of 193 nm.

The phase shift film 40 may have a transmittance of about 3% to about 10% for light with a wavelength of 193 nm. The phase shift film 40 may have a transmittance of about 4% to about 8% for light with a wavelength of 193 nm. By keeping the transmittance within these ranges, the resolution of a photomask 200 containing the phase shift film 40 may be improved.

The phase shift film 40 may include a transition metal and silicon. The phase shift film 40 may include a transition metal, silicon, oxygen and nitrogen. The transition metal may be molybdenum.

A hard mask (not shown) may be placed on the light-shielding film 30. The hard mask may function as an etching mask film when etching the pattern of the light-shielding film 30. The hard mask may include silicon, nitrogen and oxygen.

A method of fabricating the optical substrate 10 includes an operation of forming the light-shielding film 30 on the light-transmissive substrate 20. The light-shielding film 30 may be formed by a sputtering process.

After the sputtering process proceeds, a heat treatment process may proceed.

The heat treatment step may be performed at about 200° C. to about 400° C.

The heat treatment step may be performed for about 5 minutes to about 30 minutes.

In addition, the method of fabricating the optical substrate 10 may further include an operation of cooling the light-shielding film 30 that has been subjected to the heat treatment process.

The sputtering target may be selected considering the composition of the light-shielding film 30 to be formed. The sputtering target may be applied with a single target containing a transition metal. The sputtering target may be applied with two or more targets including one target containing a transition metal. The target containing a transition metal may contain 90 atom % or more of a transition metal. The target containing a transition metal may contain 95 atom % or more of a transition metal. The target containing a transition metal may include 99 atom % of a transition metal.

The transition metal may include at least one of Cr, Ta, Ti and Hf. The transition metal may include Cr.

The atmospheric gas may include inert gas, reactive gas and sputtering gas. The inert gas does not contain elements constituting a formed thin film. The reactive gas contains elements constituting a formed thin film.

The sputtering gas ionizes in a plasma atmosphere and collides with a target. The inert gas may include helium.

The reactive gas may include a gas containing nitrogen element. The gas containing the nitrogen element may be, for example, N₂, NO, NO₂, N₂O, N₂O₃, N₂O₄, N₂O₅ or the like. The reactive gas may include a gas containing an oxygen element.

The gas containing the oxygen element may be, for example, O₂. The reactive gas may include a gas containing nitrogen element and a gas containing oxygen element. The reactive gas may include a gas containing both nitrogen element and oxygen element. The gas containing both the nitrogen element and the oxygen element may be, for example, NO, NO₂, N₂O, N₂O₃, N₂O₄, N₂O₅, or the like.

In addition, the reactive gas containing carbon and oxygen may be CO₂.

The sputtering gas may be Ar gas.

A power source that applies power to the sputtering target may be either DC power or RF power.

Next, the cooled light-shielding film 30 may be cleaned. The cleaning process may include an ultraviolet irradiation process and/or a rinse process.

The ultraviolet irradiation process may include an operation of irradiating ultraviolet rays to the light-shielding film 30.

The rinse process includes an operation of treating the light-shielding film 30 with a cleaning solution. The cleaning solution may include at least one of deionized water, hydrogen water, ozone water and carbonated water. The cleaning solution may include the carbonated water.

As shown in FIG. 4, a coating device is prepared to form a photoresist layer 50 on the optical substrate 10. The coating device includes a chamber 100, a chuck 200, an exhaust part 400, a photoresist resin composition-supplying part 500 and a spindle motor 700.

The chamber 100 accommodates the chuck 200. The chamber 100 may accommodate the optical substrate 10 to manufacture a blank mask. The inside of the chamber 100 may be isolated from the outside. The pressure inside the chamber 100 may be vacuumed to be lower than the atmospheric pressure.

In addition, the chamber 100 may include a door or cover that can be opened and closed. The chamber 100 may be equipped with a heater or the like that can control the temperature inside the chamber 100.

The chuck 200 may include a support part 210 and a guide part 220.

The support part 210 may support the guide part 220 and a byproduct removal part 230 The support part 210 supports the optical substrate 10. The support part 210 may be disposed under the optical substrate 10.

The support part 210 may temporarily fix the optical substrate 10. The support part 210 may temporarily fix the optical substrate 10 by vacuum pressure or electrostatic force.

The guide part 220 may be connected to the support part 210. The guide part 220 may be formed integrally with the support part 210. The guide part 220 may be disposed on a side surface 12 of the optical substrate 10. The guide part 220 may surround the side surface 12 of the optical substrate 10.

An accommodating part 240 that accommodates the optical substrate 10 may be formed by the support part 210 and the guide part 220. That is, the support part 210 may be disposed on the bottom side 13 of the optical substrate 10, and the guide part 220 may be disposed on the side surface 12 of the optical substrate 10, thereby constituting the accommodating part 240.

The accommodating part 240 may correspond to the planar shape of the optical substrate 10. The planar shape of the accommodating part 240 may be almost similar to the planar shape of the optical substrate 10. The planar shape of the optical substrate 10 may be square, and the planar shape of the accommodating part 240 may also be square.

The outer edge of the guide part 220 may have a circular shape. The guide part 220 and the support part 210 may have a circular shape.

The exhaust part 400 may exhaust gas inside the chamber 100. In addition, the exhaust part 400 may discharge a photoresist resin composition remaining after being coated on the optical substrate 10. The exhaust part 400 may discharge a photoresist resin composition that is scattered to the side of the chuck 200.

The photoresist resin composition-supplying part 500 may supply the photoresist resin composition 510 to the top side of the optical substrate 10. The photoresist resin composition 510 may include a spray nozzle 520 disposed in the chamber 100. The photoresist resin composition 510 may be dropped onto the optical substrate 10 through the spray nozzle 520. That is, the photoresist resin composition-supplying part 500 may spray the photoresist resin composition 510 to the top side of the optical substrate 10.

The photoresist resin composition may be a negative-type actinic light-sensitive or radiation-sensitive resin composition. The photoresist resin composition may be a negative-type resist composition for pattern formation, a negative-type resist composition for organic solvent development, or a negative-type resist composition for alkaline development. The photoresist resin composition may be typically a chemically amplified resist composition.

The photoresist resin composition may include a binder resin, a photosensitive agent (or photosensitizer) and an organic solvent.

Examples of the binder resin include Novolac resin, phenolic resin, epoxy resin, polyimide resin, and the like. Examples of the binder resin include polyvinyl pyrrolidone, poly (acrylamide-co-diacetoneacrylamide), and the like.

For example, the photosensitizer may be selected from the group consisting of 4,4′-diazido-2,2′-stilbendisulfonate sodium salt, 4,4′-diazo-2,2′-dibenzalacetone disulfonate disodium salt, 2,5-bis(4-azido-2-sulfobenzylidene)cyclopentanone disodium salt and 4,4′-diazido 2,2′-dicinnamylideneacetone sulfonate salt (DACA).

For example, the solvent may be selected from the group consisting of ethyl acetate, butyl acetate, diethylene glycol dimethyl ether, diethylene glycol dimethyl ethyl ether, dipropylene glycol dimethyl ether, methyl methoxypropionate, ethyl ethoxy propionate (EEP), ethyl lactate, propylene glycol methyl ether acetate (PGMEA), propylene glycol methyl ether, propylene glycol propyl ether, methyl cellosolve acetate, ethyl cellosolve acetate, diethylene glycol methyl acetate, diethylene glycol ethyl acetone, methyl isobutyl ketone, cyclohexanone, dimethylformamide (DMF), N,N-dimethylacetamide (DMac), N-methyl-2-pyrrolidone (NMP), γ-butyrolactone, diethyl ether, ethylene glycol dimethyl ether, diglyme, tetrahydrofuran (THF), methanol, ethanol, propanol, iso-propanol, methyl cellosolve, ethyl cellosolve, diethylene glycol methyl ether, diethylene glycol ethyl ether, dipropylene glycol methyl ether, toluene, xylene, hexane, heptane and octane.

The content of solids, except for the solvent, of the photoresist resin composition may be about 3 wt % to about 20 wt % based on the total weight. The content of solids, except for the solvent, of the photoresist resin composition may be about 3 wt % to about 15 wt % based on the total weight. The content of solids, except for the solvent, of the photoresist resin composition may be about 5 wt % to about 10 wt % based on the total weight.

The photoresist resin composition may include the binder resin in a content of about 2 wt % to about 50 wt % based on the total weight. The photoresist resin composition may include the binder resin in a content of about 3 wt % to about 15 wt %.

The photoresist composition may include the photosensitive agent in a content of about 0.5 wt % to about 40 wt %. The photoresist composition may include the photosensitive agent in a content of about 0.5 wt % to about 20 wt %. The photoresist composition may include the photosensitive agent in a content of about 0.5 wt % to about 10 wt %. The photoresist composition may include the photosensitive agent in a content of about 0.5 wt % to about 5 wt %.

The viscosity of the photoresist composition may be about 0.5 cPs to about 10 cPs. The viscosity of the photoresist composition may be about 1 cPs to about 5 cPs. The viscosity of the photoresist composition may be about 0.5 cPs to about 5 cPs.

The photoresist resin composition may further include an additive such as a leveling agent or an adhesion aid.

The optical substrate 10 may be disposed in the chamber 100. The optical substrate 10 may be temporarily fixed to the chuck 200. The optical substrate 10 may be disposed in a receiving part formed by the chuck 200. The optical substrate 10 may be seated on the chuck 200.

The photoresist layer 50 is formed on the optical substrate 10 using the coating device.

To form the photoresist layer 50, the inside of the chamber 100 is isolated from the outside by a cover of the chamber 100. Next, in a state where the chuck 200 rotates at high speed, the photoresist resin composition is dropped and coated on the top surface of the optical substrate 10 by the photoresist resin composition supply part 500. Accordingly, a photoresist resin composition layer may be formed on the optical substrate 10.

Here, the chuck 200 may rotate the optical substrate 10 by the following method.

First, the optical substrate 10 may undergo a first rotation operation. The first rotation operation may be performed at about 20° C. to about 30° co. The first rotation operation may be performed at about 20° C. to about 27° C.

The first rotation operation may have a first rotation speed. The first rotation speed may be about 30 rpm to about 70 rpm or about 40 rpm to about 60 rpm. The first rotation operation may be performed for about 1 sec to about 5 sec or about 2 sec to about 4 sec.

In addition, in the first rotation operation, the photoresist resin composition may be dropped onto the optical substrate 10. The dropping rate of the photoresist composition may be about 0.5 ml/sec to about 5 ml/sec or about 1 ml/sec to about 4 ml/sec.

After the first rotation operation, the optical substrate 10 may undergo a second rotation operation. The second rotation operation may be performed at about 20° C. to about 30° C. The second rotation operation may have a second rotation speed. The second rotation speed may be about 50 rpm to about 100 rpm or about 60 rpm to about 90 rpm. The second rotation speed may be higher than the speed of the first rotation operation. The second rotation speed may be faster than the first rotation speed by about 5 rpm to about 70 rpm, about 10 rpm to about 70 rpm or about 20 rpm to about 70 rpm. The second rotation operation may be performed for about 3 sec to about 10 sec.

After the second rotation operation, the optical substrate 10 may undergo a third rotation operation. The third rotation operation may be performed at about 20° C. to about 30° C. The third rotation operation may have a third rotation speed. The third rotation speed may be about 100 rpm to about 150 rpm, about 110 rpm to about 140 rpm or about 110 rpm to about 130 rpm. The third rotation speed may be faster than the second rotation operation. The third rotation speed may be faster than the second rotation speed by about 5 rpm to about 70 rpm, about 10 rpm to about 70 rpm or about 20 rpm to about 70 rpm. The third rotation operation may be performed for about 5 sec to about 13 sec or about 6 sec to about 12 sec.

After the third rotation operation, the optical substrate 10 may undergo a fourth rotation operation. The fourth rotation operation may be performed at about 20° C. to about 30° C. The fourth rotation operation may have a fourth rotation speed. The fourth rotation speed may be about 800 rpm to about 3000 rpm. The fourth rotation speed may be about 800 rpm to about 1500 rpm. The fourth rotation speed may be about 1500 rpm to about 2500 rpm. The fourth rotation speed may be about 2000 rpm to about 3000 rpm. The fourth rotation speed may be faster than the third rotation speed. The fourth rotation speed may be faster than the third rotation speed by about 700 rpm to about 2800 rpm. The speed of the fourth rotation operation may be higher than the speed of the third rotation operation by about 500 rpm to about 2500 rpm. The fourth rotation operation may be performed for about 0.5 sec to about 2 sec.

After the fourth rotation operation, the optical substrate 10 may undergo a fifth rotation operation. The fifth rotation operation may be performed at about 20° C. to about 30° C. The fifth rotation speed may be about 500 rpm to about 2500 rpm. The fifth rotation speed may be about 500 rpm to about 1200 rpm. The fifth rotation speed may be about 1000 rpm to about 2000 rpm. The fifth rotation speed may be about 1500 rpm to about 2500 rpm. The fifth rotation speed may be lower than the fourth rotation speed. The fifth rotation speed may be lower than the fourth rotation speed by about 300 rpm to about 1500 rpm. The fifth rotation operation may be performed for about 1 sec to about 5 sec.

After the fifth rotation operation, the optical substrate 10 may undergo a sixth rotation operation. The sixth rotation operation may be performed at about 20° C. to about 30° C. The sixth rotation operation may have a sixth rotation speed. The sixth rotation speed may be about 100 rpm to about 500 rpm. The sixth rotation speed may be about 100 rpm to about 400 rpm. The sixth rotation speed may be about 100 rpm to about 300 rpm. The sixth rotation speed may be about 200 rpm to about 400 rpm. The sixth rotation speed may be lower than the fifth rotation speed. The sixth rotation speed may be lower than the fifth rotation speed by about 200 rpm to about 2300 rpm. The sixth rotation operation may be performed for about 30 sec to about 60 sec.

In the sixth rotation operation, the photoresist resin composition layer formed on the optical substrate 10 may be dried, and the solvent may be removed.

Accordingly, the photoresist layer 50 may be formed on the optical substrate 10 as shown in FIG. 5. Accordingly, a blank mask including the optical substrate 10 and the photoresist layer 50 may be fabricated.

As shown in FIG. 6, the photoresist layer 50 may include a flat portion 51 and optical irregularities 52 and 53.

The flat portion 51 may have a uniform thickness overall. In addition, the flat portion 51 may have a thickness variation of less than about 100 Å overall. The flat portion 51 may have a thickness variation of less than about 90 Å overall. The flat portion 51 may have a thickness variation of less than about 80 Å overall. The flat portion 51 may have a thickness variation of less than about 50 Å overall. The thickness variation may be a difference between the maximum thickness and minimum thickness of the flat portion 51.

The thickness of the flat portion 51 may be measured with an ellipsometer. The thickness of the flat portion 51 may be measured with the SE MG series, SE MF series, SE MH series or SE MI series, etc. manufactured by Nano-View Company.

The thickness of the flat portion 51 may be about 1000 Å to about 10000 Å. The thickness of the flat portion 51 may be about 1000 Å to about 5000 Å. The thickness of the flat portion 51 may be about 1000 Å to about 4000 Å.

The optical irregularities 52 and 53 may have optical thicknesses different from the flat portion 51. The optical thickness of the flat portion 51 may be derived from the product of the refractive index of the flat portion 51 and the thickness of the flat portion 51. In addition, the optical thickness of the optical irregularities 52 and 53 may be derived from the product of the refractive index of the optical irregularities 52 and 53 and the thickness of the optical irregularities 52 and 53.

The difference between the optical thickness of the flat portion 51 and the optical thickness of the optical irregularities 52 and 53 may be greater than about 5 nm. The difference between the optical thickness of the flat portion 51 and the optical thickness of the optical irregularities 52 and 53 may be greater than about 10 nm. The difference between the optical thickness of the flat portion 51 and the optical thickness of the optical irregularities 52 and 53 may be greater than about 15 nm. The difference between the optical thickness of the flat portion 51 and the optical thickness of the optical irregularities 52 and 53 may be greater than about 20 nm. The difference between the optical thickness of the flat portion 51 and the optical thickness of the optical irregularities 52 and 53 may be greater than about 30 nm. The difference between the optical thickness of the flat portion 51 and the optical thickness of the optical irregularities 52 and 53 may be greater than about 40 nm. The difference between the optical thickness of the flat portion 51 and the optical thickness of the optical irregularities 52 and 53 may be greater than about 50 nm.

The maximum value of the difference between the optical thickness of the flat portion 51 and the optical thickness of the optical irregularities 52 and 53 may be about 500 nm.

The diameters of the optical irregularities 52 and 53 may be greater than about 10 nm. The diameters of the optical irregularities 52 and 53 may be greater than about 20 nm. The diameters of the optical irregularities 52 and 53 may be greater than about 30 nm. The diameters of the optical irregularities 52 and 53 may be greater than about 40 nm. The diameters of the optical irregularities 52 and 53 may be greater than about 50 nm. The diameters of the optical irregularities 52 and 53 may be greater than about 70 nm. The diameters of the optical irregularities 52 and 53 may be greater than about 100 nm.

The maximum value of the diameters of the optical irregularities 52 and 53 may be about 500 nm.

In addition, the optical irregularities 52 and 53 may include an optical path-changing part. The optical path-changing part may change the path of incident light. The path of light incident on the optical irregularities 52 and 53 is distorted by the optical path-changing part, so that the incident angle of the light and the reflection angle on the optical irregularities 52 and 53 may be different from each other.

That is, for light incident at the same angle, the reflection angle of the flat portion 51 and the reflection angle of the optical irregularities 52 and 53 may be different from each other.

The optical irregularities 52 and 53 may include a curved surface. The optical path-changing part may include the curved surfaces of the optical irregularities 52 and 53.

As shown in FIG. 8, the optical irregularities 52 and 53 may include a first optical irregularity 52. The first optical irregularity 52 may be disposed inside the photoresist layer 50. The first optical irregularity 52 may be arranged in a form that is immersed in the photoresist layer 50

The first optical irregularity 52 may have a refractive index different from that of the flat portion 51. A difference between the refractive index of the first optical irregularity 52 and the refractive index of the flat portion 51 may be about 0.05 to about 0.7, 0.03 to about 0.5, 0.01 to about 0.3, 0.1 to about 0.9 or about 0.1 to about 0.8. Accordingly, the optical path may be changed at the boundary surface between the first optical irregularity 52 and the flat portion 51. That is, the reflection angle may be changed at the boundary surface between the first optical irregularity 52 and the flat portion 51.

That is, the optical path-changing part may include the boundary surface between the first optical irregularity 52 and the flat portion 51. That is, the optical path-changing part may include the curved surface of the first optical irregularity 52.

In addition, a second optical irregularity 53 may protrude from the top side of the photoresist layer 50. That is, the surface of the photoresist layer 50 may become irregular due to the second optical irregularity 53. That is, the height of the top side of the second optical irregularity 53 may be higher than the height of the top side of the flat portion 51. A difference between the height of the top side of the second optical irregularity 53 and the height of the top side of the flat portion 51 may be about 1 nm to about 100 nm.

In addition, a portion, which protrudes from the top side of the photoresist layer 50, of the second optical irregularity 53 may have a curved surface. That is, the top side of the second optical irregularity 53 may protrude from the photoresist layer 50 and may have a curved surface.

The optical path-changing part may include the curved surface of the second optical irregularity 53. The optical path-changing part may include the exposed top side of the second optical irregularity 53.

The optical irregularities 52 and 53 may be detected by light of about 532 nm. The optical irregularities 52 and 53 may be detected by a laser of about 532 nm. The laser is irradiated to the photoresist layer 50, and the optical irregularities 52 and 53 may be detected by analyzing light reflected from the photoresist layer 50.

After the laser is irradiated to the photoresist layer 50, the reflected light may be sensed through an image sensor. The light reflected from the photoresist layer 50 may be sensed by the image sensor through a confocal and spatial filter. Next, signals sensed through the image sensor may be processed into an image of 256 grayscales of 8 bits. The image may be processed into 640×480 pixels.

In addition, when a difference exceeding about 3 grayscales occurs in the pixels of the image, it may be detected as the optical irregularities 52 and 53. When a difference exceeding about 5 grayscales occurs in the pixels of the image, it may be detected as the optical irregularities 52 and 53. When a difference exceeding about 7 grayscales occurs in the pixels of the image, it may be detected as the optical irregularities 52 and 53. When a difference exceeding about 10 grayscales occurs in the pixels of the image, it may be detected as the optical irregularities 52 and 53.

In addition, the planar area of the optical irregularities 52 and 53 may be calculated by the number of pixels detected as the optical irregularities 52 and 53 in the image.

The optical irregularities 52 and 53 may be detected with optical surface inspection equipment. The optical irregularities 52 and 53 may be detected with M6640S or M6641S manufactured by LASERTEC.

In the photoresist layer 50, the number of the optical irregularities 52 and 53 may be less than about 50/36 inches². In the photoresist layer 50, the number of the optical irregularities 52 and 53 may be less than about 40/36 inches². In the photoresist layer 50, the number of the optical irregularities 52 and 53 may be less than about 30/36 inches². In the photoresist layer 50, the number of the optical irregularities 52 and 53 may be less than about 20/36 inches². In the photoresist layer 50, the number of the optical irregularities 52 and 53 may be less than about 10/36 inches².

In the photoresist layer 50, the number of the optical irregularities 52 and 53 may be about 1/36 inches² or more and less than about 50/36 inches². In the photoresist layer 50, the number of the optical irregularities 52 and 53 may be about 1/36 inches² or more and less than about 40/36 inches². In the photoresist layer 50, the number of the optical irregularities 52 and 53 may be about 1/36 inches² or more and less than about 30/36 inches². In the photoresist layer 50, the number of the optical irregularities 52 and 53 may be about 1/36 inches² or more and less than about 20/36 inches². In the photoresist layer 50, the number of the optical irregularities 52 and 53 may be about 1/36 inches² or more and less than about 10/36 inches².

Since the photoresist layer 50 includes the optical irregularities 52 and 53 in the above-mentioned number, the photoresist layer 50 may be precisely developed. That is, since the photoresist layer 50 includes the optical irregularities 52 and 53 in the above-mentioned number, the precision of the photoresist layer 50 in an exposure process may be improved. Accordingly, the method of fabricating a blank mask according to an embodiment may provide a precise photomask.

As shown in FIG. 7, the photoresist layer 50 may include 49 regions.

The 49 regions may be set by seven virtual straight lines arranged horizontally at regular intervals and seven virtual straight lines arranged vertically at regular intervals. That is, the 49 regions may be formed by dividing the photoresist layer 50 into 7 at regular intervals in the horizontal direction and into 7 at regular intervals in the vertical direction, when viewed from a plane. That is, the 49 regions may have a square shape and may divide the photoresist into the same size. For example, the 49 regions may be squares having a width and height of 6/7 inches.

In addition, the 49 regions may include a first centrally positioned region 1-1, second regions 2-1 to 2-8, third regions 3-1 to 3-16 and fourth regions 4-1 to 4-24.

The first region 1-1 may be located at the center of the photoresist layer 50. In more detail, the first region 1-1 may be located at the exact center of the photoresist layer 50.

The second regions 2-1 to 2-8 may be arranged around the first region 1-1. The second regions 2-1 to 2-8 may surround the first region 1-1. The second regions 2-1 to 2-8 may be directly adjacent to the first region 1-1.

The third regions 3-1 to 3-16 may be arranged around the second regions 2-1 to 2-8. The third regions 3-1 to 3-16 may surround the second regions 2-1 to 2-8. The third regions 3-1 to 3-16 may be directly adjacent to the second regions 2-1 to 2-8.

The fourth regions 4-1 to 4-24 may be arranged around the third regions 3-1 to 3-16. The fourth regions 4-1 to 4-24 may surround the third regions 3-1 to 3-16. The fourth regions 4-1 to 4-24 may be directly adjacent to the third regions 3-1 to 3-16. The fourth regions 4-1 to 4-24 may be located at the outermost part of the photoresist layer 50.

In the 49 regions, a thickness variation of the photoresist layer 50 may be less than about 100 Å. The thickness variation may be a difference between the largest and smallest thicknesses of the 49 regions. In the 49 regions, the thickness variation of the photoresist layer 50 may be less than about 90 Å. In the 49 regions, the thickness variation of the photoresist layer 50 may be less than about 80 Å. In the 49 regions, the thickness variation of the photoresist layer 50 may be less than about 70 Å. In the 49 regions, the thickness variation of the photoresist layer 50 may be less than about 60 Å. In the 49 regions, the thickness variation of the photoresist layer 50 may be less than about 50 Å.

In the 49 regions, the minimum value of the thickness variation of the photoresist layer 50 may be about 3 Å.

In the photoresist layer 50, the average thickness of the fourth regions 4-1 to 4-24 may be thicker than the average thickness of the third regions 3-1 to 3-16. In the photoresist layer 50, the average thickness of the fourth regions 4-1 to 4-24 may be about 3 Å to about 10 Å thicker than the average thickness of the third regions 3-1 to 3-16 In the photoresist layer 50, the average thickness of the fourth regions 4-1 to 4-24 may be about 4 Å to about 10 Å thicker than the average thickness of the third regions 3-1 to 3-16. In the photoresist layer 50, the average thickness of the fourth regions 4-1 to 4-24 may be about 5 Å to about 10 Å thicker than the average thickness of the third regions 3-1 to 3-16.

In the photoresist layer 50, the average thickness of the fourth regions 4-1 to 4-24 may be thicker than the average thickness of the second regions 2-1 to 2-8. In the photoresist layer 50, the average thickness of the fourth regions 4-1 to 4-24 may be about 3 Å to about 10 Å thicker than the average thickness of the second regions 2-1 to 2-8. In the photoresist layer 50, the average thickness of the fourth regions 4-1 to 4-24 may be about 4 Å to about 10 Å thicker than the average thickness of the second regions 2-1 to 2-8. In the photoresist layer 50, the average thickness of the fourth regions 4-1 to 4-24 may be about 5 Å to about 10 Å thicker than the average thickness of the second regions 2-1 to 2-8.

In the photoresist layer 50, the average thickness of the fourth regions 4-1 to 4-24 may be thicker than the average thickness of the first region 1-1. In the photoresist layer 50, the average thickness of the fourth regions 4-1 to 4-24 may be about 3 Å to about 10 Å thicker than the average thickness of the first region 1-1. In the photoresist layer 50, the average thickness of the fourth regions 4-1 to 4-24 may be about 4 Å to about 10 Å thicker than the average thickness of the first region 1-1. In the photoresist layer 50, the average thickness of the fourth regions 4-1 to 4-24 may be about 5 Å to about 10 Å thicker than the average thickness of the first region 1-1.

In the photoresist layer 50, the average thickness of the first region 1-1 may be thicker than the average thickness of the second regions 2-1 to 2-8. In the photoresist layer 50, the average thickness of the first region 1-1 may be about 3 Å to about 10 Å thicker than the average thickness of the second regions 2-1 to 2-8. In the photoresist layer 50, the average thickness of the first region 1-1 may be about 4 Å to about 10 Å thicker than the average thickness of the second regions 2-1 to 2-8. In the photoresist layer 50, the average thickness of the first region 1-1 may be about 5 Å to about 10 Å thicker than the average thickness of the second regions 2-1 to 2-8.

In the photoresist layer 50, the average thickness of the first region 1-1 may be thicker than the average thickness of the third regions 3-1 to 3-16. In the photoresist layer 50, the average thickness of the first region 1-1 may be about 3 Å to about 10 Å thicker than the average thickness of the third regions 3-1 to 3-16. In the photoresist layer 50, the average thickness of the first region 1-1 may be about 4 Å to about 10 Å thicker than the average thickness of the third regions 3-1 to 3-16. In the photoresist layer 50, the average thickness of the first region 1-1 may be about 5 Å to about 10 Å thicker than the average thickness of the third regions 3-1 to 3-16.

The density of optical irregularities in the fourth regions 4-1 to 4-24 may be greater than the density of optical irregularities in the first region 1-1, the second regions 2-1 to 2-8 and the third regions 3-1 to 3-16. The density of optical irregularities is a value obtained by dividing the number of optical irregularities by the area of the region where the optical irregularities are located.

That is, the density of optical irregularities in the fourth regions 4-1 to 4-24 may be a value obtained by dividing the total number of optical irregularities arranged in the fourth regions 4-1 to 4-24 by the total area of the fourth regions 4-1 to 4-24.

In addition, the density of optical irregularities in the first region 1-1, the second regions 2-1 to 2-8 and the third regions 3-1 to 3-16 is a value obtained by dividing the total number of optical irregularities arranged in the first region 1-1, the second regions 2-1 to 2-8 and the third regions 3-1 to 3-16 by the total area of the first region 1-1, the second regions 2-1 to 2-8 and the third regions 3-1 to 3-16.

The density of optical irregularities in the fourth regions 4-1 to 4-24 may be about 15/36 inches² to 25/36 inches². The density of optical irregularities in the fourth regions 4-1 to 4-24 may be about 10/36 inches² to 30/36 inches². The density of optical irregularities in the fourth regions 4-1 to 4-24 may be about 17/36 inches² to 22/36 inches².

The density of optical irregularities in the first region 1-1, the second regions 2-1 to 2-8 and the third regions 3-1 to 3-16 may be about 5/36 inches² to 20/36 inches². The density of optical irregularities in the first region 1-1, the second regions 2-1 to 2-8 and the third regions 3-1 to 3-16 may be about 3/36 inches² to 25/36 inches². The density of optical irregularities in the first region 1-1, the second regions 2-1 to 2-8 and the third regions 3-1 to 3-16 may be about 7/36 inches² to 15/36 inches².

The difference between the density of optical irregularities in the fourth regions 4-1 to 4-24 and the density of optical irregularities in the first region 1-1, the second regions 2-1 to 2-8 and the third regions 3-1 to 3-16 may be about 1/36 inches² to 20/36 inches². The difference between the density of optical irregularities in the fourth regions 4-1 to 4-24 and the density of optical irregularities in the first region 1-1, the second regions 2-1 to 2-8 and the third regions 3-1 to 3-16 may be about 1/36 inches² to 15/36 inches². The difference between the density of optical irregularities in the fourth regions 4-1 to 4-24 and the density of optical irregularities in the first region 1-1, the second regions 2-1 to 2-8 and the third regions 3-1 to 3-16 may be about 3/36 inches² to 15/36 inches². The difference between the density of optical irregularities in the fourth regions 4-1 to 4-24 and the density of optical irregularities in the first region 1-1, the second regions 2-1 to 2-8 and the third regions 3-1 to 3-16 may be about 5/36 inches² to 10/36 inches².

In addition, the number of the optical irregularities in each of the fourth areas may be 3 or less. The number of the optical irregularities in each of the fourth areas may be 2 or less.

In addition, the number of the optical irregularities in each of the third areas may be 3 or less. The number of the optical irregularities in each of the third areas may be 2 or less.

In addition, the number of the optical irregularities in each of the second areas may be 3 or less. The number of the optical irregularities in each of the second areas may be 2 or less.

In addition, the number of the optical irregularities in the first region 1-1 may be 3 or less. The number of the optical irregularities in the first region 1-1 may be 2 or less.

In addition, the total number of the optical irregularities in the fourth regions 4-1 to 4-24 may be about 1 to about 20. The total number of the optical irregularities in the fourth regions 4-1 to 4-24 may be about 3 to about 15.

In addition, in the first region 1-1, the second regions 2-1 to 2-8 and the third regions 3-1 to 3-16, the total number of the optical irregularities may be 0 to about 15. In the first region 1-1, the second regions 2-1 to 2-8 and the third regions 3-1 to 3-16, the total number of the optical irregularities may be 1 to about 10. In the first region 1-1, the second regions 2-1 to 2-8 and the third regions 3-1 to 3-16, the total number of the optical irregularities may be 2 to about 7.

Light is selectively irradiated to the photoresist layer 50, and the light-shielding film is selectively etched, thereby forming the light-shielding pattern film 35. Accordingly, a photomask 2 including the light-transmissive substrate 20 and the light-shielding pattern film 35 disposed on the light-transmissive substrate 20 may be formed as shown in FIG. 8

The light-shielding pattern film 35 includes a transition metal and at least one of oxygen and nitrogen.

The light-shielding pattern film 35 may be formed by patterning the light-shielding film 30 of the blank mask 100 as described above.

Descriptions of the physical properties, composition and structure of the light-shielding pattern film 35 are omitted as they overlap with the descriptions of the light-shielding film 30 of the blank mask 1.

A method of fabricating a semiconductor device according to an embodiment includes an operation of placing a light source, a photomask 2 and a semiconductor wafer coated with a resist film; an exposure operation of selectively transmitting and emitting light, incident from the light source, onto a semiconductor wafer through the photomask 2; and a development operation of developing a pattern on the semiconductor wafer.

The photomask 2 includes the light-transmissive substrate 20; and the light-shielding pattern film 35 disposed on the light-transmissive substrate 20.

The light-shielding pattern film 35 includes a transition metal and at least one of oxygen, nitrogen and carbon.

In the preparation operation, the light source is a device capable of generating short-wavelength exposure light. The exposure light may be light having a wavelength of 200 nm. The exposure light may be arf light having a wavelength of 193 nm.

A lens may be additionally disposed between the photomask 2 and the semiconductor wafer. The lens has the function of reducing the circuit pattern shape on the photomask 2 and transferring it onto the semiconductor wafer. The lens is not limited as long as it can be generally applied to an Arf semiconductor wafer exposure process. For example, the lens may be a lens made of calcium fluoride (CaF₂).

In the exposure operation, exposure light may be selectively transmitted onto the semiconductor wafer through the photomask 2. In this case, chemical degeneration may occur in a resist film part on which exposure light is incident.

In the development operation, the semiconductor wafer that has been subjected to the exposure operation may be treated with a developing solution to develop a pattern on the semiconductor wafer. When the applied resist film is a positive resist, a resist film part on which exposure light is incident may be dissolved by the developing solution. When the applied resist film is a negative resist, a resist film part on which exposure light is not incident may be dissolved by the developing solution. The resist film is formed into a resist pattern by treatment with the developing solution. A pattern may be formed on the semiconductor wafer using the resist pattern as a mask.

A description of the photomask 2 is omitted as it overlaps with the previous content.

A method of fabricating the blank mask according to an embodiment includes an operation of maintaining a state where a photoresist composition is filled inside a nozzle 520 that sprays a photoresist composition. In addition, the method of fabricating the blank mask according to an embodiment includes an operation of removing the photoresist composition inside the nozzle 520. Accordingly, a residue attached to the inside of the nozzle 520 may be easily removed.

The method of fabricating the blank mask according to an embodiment may prevent the residue 513 from being introduced into the photoresist layer 50.

Accordingly, the blank mask according to an embodiment may reduce the number of the optical irregularities 52 and 53 that may be caused by the residue, etc. The blank mask according to an embodiment may include the optical irregularities 52 and 53 in a number of less than 30/36 inches².

A method of fabricating the blank mask according to an embodiment may implement the photoresist layer 50 having optical flatness overall. Accordingly, the photoresist layer 50 may precisely pattern the light-shielding film.

The blank mask according to an embodiment may include the photoresist layer 50 having a high thickness uniformity overall. Accordingly, the photoresist layer 50 may be precisely patterned in the exposure and development process. The blank mask according to an embodiment may precisely pattern the light-shielding film and provide a precise photomask.

In particular, in the blank mask according to an embodiment, the photoresist layer 50 may have an outer edge region that is relatively thicker. That is, the process conditions are controlled such that the outer edge region of the photoresist layer 50 is formed to be relatively slightly thicker, so that the photoresist layer 50 may have a uniform thickness overall.

In addition, the process of forming the photoresist layer 50 may include first to sixth rotation operations. Accordingly, the photoresist layer 50 may have a uniform thickness overall. In addition, since the photoresist layer 50 is formed by the above-described process, it may have an outer edge region that is relatively slightly thicker.

In addition, the photoresist layer 50 may include optical irregularities. In particular, the photoresist layer 50 may be formed such that its outer edge region has a higher optical density. Accordingly, the photoresist layer 50 may reduce the number of optical irregularities overall.

In particular, the blank mask according to an embodiment may include the optical irregularities in a number of less than 30/36 inches².

A method of fabricating the blank mask according to an embodiment may implement the photoresist layer 50 having optical flatness overall. Accordingly, the photoresist layer 50 may precisely pattern the light-shielding film.

In particular, since the photoresist layer 50 has optical irregularities, detected by the 532 nm laser, in the above-mentioned number as described above, it may be precisely developed by ultraviolet rays.

Accordingly, the blank mask according to an embodiment may provide a photomask having a precise pattern.

The blank mask according to an embodiment may reduce the number of the optical irregularities 52 and 53 that can be caused by the residue 513, etc. The blank mask according to an embodiment may include the optical irregularities 52 and 53 in a number of less than 30/36 inches².

A method of fabricating the blank mask according to an embodiment may implement the photoresist layer 50 having optical flatness overall. Accordingly, the photoresist layer 50 may precisely pattern the light-shielding film.

The blank mask according to an embodiment may provide a photomask having a precise pattern.

The apparatus for fabricating a blank mask according to an embodiment and a method thereof may provide a blank mask having improved performance.

Although the embodiments of the present disclosure have been described in detail above, the scope of the present disclosure is not limited thereto, and various modifications and improvements made by those skilled in the art using the basic concepts of the embodiments which are defined in the accompanying claims, are also within the scope of the present disclosure. Furthermore, the embodiments may be combined to form additional embodiments.

### Preparation Examples

### Photoresist Composition #1

FEP171 solution (FUJIFILM Arch Co, Ltd) was used, and a mixture of propylene glycolmonomethyl ether acetate (PGMEA) and propylene glycol monomethyl ether (PGME) mixed in a ratio of 8 to 2 was used. In addition, the content of solids in FEP171 solution was about 8.5 wt %. The viscosity of FEP171 solution was about 3 cP.

### Photoresist Composition #2

XFP255 solution (FUJIFILM Arch Co, Ltd) was used, and a mixture of propylene glycolmonomethyl ether acetate (PGMEA) and propylene glycol monomethyl ether (PGME) mixed in a ratio of 8 to 2 was used as a solvent. In addition, the content of solids in XFP255 solution was about 6.5 wt %. The viscosity of XFP255 solution was about 1.5 cP.

### Example 1

A quartz substrate having a size of about 6 inches×about 6 inches was used, and the thickness of the quartz substrate was 0.25 inches. On the quartz substrate, a MoSi film was formed to a thickness of about 600 to 1000 Å and a Cr film was formed to a thickness of about (500 to 900 Å) by a sputtering process. Next, the quartz substrate where the MoSi and Cr films had been formed was placed on a chuck.

After the FEP171 solution was dropped on the quartz substrate from a nozzle at a height of about 0.5 cm, the quartz substrate was rotated at a speed of about 50 rpm at a temperature of about 23 degrees for about 3 sec (operation 1). Next, the quartz substrate was rotated at a speed of about 80 rpm at a temperature of about 23 degrees for 5 sec (operation 2), was rotated at a speed of about 100 rpm at a temperature of about 23 degrees for 8 sec (operation 3), was rotated at a speed of about 2200 rpm at a temperature of about 23 degrees for 1 sec (operation 4), and was rotated at a speed of about 1750 rpm at a temperature of about 23 degrees for 3 sec (operation 5).

Next, the quartz substrate was rotated at a temperature of about 23 degrees at a speed of about 300 rpm for 40 sec (operation 6).

As a result, an optical substrate on which a photoresist layer had been formed was produced.

### Examples 2 to 5 and Comparative Examples

As shown in Tables 1 and 2 below, a nozzle height, a resist composition and coating conditions were adjusted. Other processes can be referred to from Example 1.

TABLE 1

| | | Nozzle | Step 1 | Step 2 |
|---|---|---|---|---|
| | Resist | height | (sec, rpm, | (sec, rpm, |
| Classification | composition | (cm) | ° C.) | ° C.) |
| Example 1 | #1viscosity 3 cP | 0.5 | 3 sec | 5 sec |
| | | | 50 rpm | 80 rpm |
| | | | 23° C. | 23° C. |
| Example 2 | #2viscosity 3 cP | 1.0 | 3 sec | 5 sec |
| | | | 50 rpm | 80 rpm |
| | | | 23° C. | 23° C. |
| Example 3 | #3viscosity 3 cP | 0.5 | 3 sec | 5 sec |
| | | | 50 rpm | 80 rpm |
| | | | 23° C. | 23° C. |
| Example 4 | #4viscosity 1.5 cP | 0.5 | 3 sec | 5 sec |
| | | | 50 rpm | 80 rpm |
| | | | 23° C. | 23° C. |
| Example 5 | #5viscosity 1.5 cP | 1.0 | 3 sec | 5 sec |
| | | | 50 rpm | 80 rpm |
| | | | 23° C. | 23° C. |
| Comparative | #5viscosity 3 cP | 0.5 | 3 sec | 5 sec |
| Example 1 | | | 50 rpm | 80 rpm |
| | | | 23° C. | 23° C. |
| Comparative | #5viscosity 3 cP | 0.5 | 3 sec | 5 sec |
| Example 2 | | | 50 rpm | 80 rpm |
| | | | 23° C. | 23° C. |
| Comparative | #5viscosity 1.5 cP | 0.5 | 3 sec | 5 sec |
| Example 3 | | | 50 rpm | 80 rpm |
| | | | 23° C. | 23° C. |
| Comparative | #5viscosity 1.5 cP | 0.5 | 3 sec | 5 sec |
| Example 4 | | | 50 rpm | 80 rpm |
| | | | 23° C. | 23° C. |

TABLE 2

| | Step 3 | Step 4 | Step 5 | Step 6 |
|---|---|---|---|---|
| | (sec, rpm, | (sec, rpm, | (sec, rpm, | (sec, rpm, |
| Classification | ° C.) | ° C.) | ° C.) | ° C.) |
| Example 1 | 8 sec | 1 sec | 3 sec | 40 sec |
| | 100 rpm | 2200 rpm | 1750 rpm | 300 rpm |
| | 23° C. | 23° C. | 23° C. | 23° C. |
| Example 2 | 8 sec | 1 sec | 3 sec | 40 sec |
| | 100 rpm | 2000 rpm | 1750 rpm | 300 rpm |
| | 23° C. | 23° C. | 23° C. | 23° C. |
| Example 3 | 8 sec | 1 sec | 3 sec | 40 sec |
| | 100 rpm | 2400 rpm | 1850 rpm | 200 rpm |
| | 23° C. | 23° C. | 23° C. | 23° C. |
| Example 4 | 8 sec | 1 sec | 3 sec | 40 sec |
| | 100 rpm | 1000 rpm | 900 rpm | 300 rpm |
| | 23° C. | 23° C. | 23° C. | 23° C. |
| Example 5 | 8 sec | 1 sec | 3 sec | 40 sec |
| | 100 rpm | 950 rpm | 850 rpm | 200 rpm |
| | 23° C. | 23° C. | 23° C. | 23° C. |
| Comparative | 4 sec | 1 sec | 3 sec | 40 sec |
| Example 1 | 100 rpm | 2200 rpm | 1750 rpm | 200 rpm |
| | 23.5° C. | 23.5° C. | 23° C. | 23° C. |
| Comparative | 8 sec | 1.5 sec | 3 sec | 40 sec |
| Example 2 | 100 rpm | 1800 rpm | 1550 rpm | 200 rpm |
| | 23° C. | 23° C. | 23° C. | 23° C. |
| Comparative | 4 sec | 1 sec | 3 sec | 40 sec |
| Example 3 | 100 rpm | 1000 rpm | 900 rpm | 200 rpm |
| | 23.5° C. | 23.5° C. | 23° C. | 23° C. |
| Comparative | 8 sec | 1.5 sec | 3 sec | 40 sec |
| Example 4 | 100 rpm | 900 rpm | 650 rpm | 200 rpm |
| | 23° C. | 23° C. | 23° C. | 23° C. |

### Evaluation Examples

### 1. Thickness of Resist Layer

The resist layer was divided into 7 equal intervals in the horizontal and vertical directions, and was divided into a total of 49 regions. The thickness of each region of the resist layer was measured. The thickness was measured using an ellipsometer (manufacturer: Nano-View CO., LTD, brand name: MG-PRO).

### 2. Number of Optical Irregularities

In the optical substrates and resist layers fabricated in the examples and comparative examples and each region thereof, the number of optical irregularities was measured using optical surface inspection equipment (M6641S manufactured by LASERTEC). The optical irregularities had a diameter of 0.01 μm to 10 μm.

As shown in Table 3 below, 49 regions of the resist layer fabricated in Example 1 were subjected to thickness measurement. Table 3 refers to the FIG. 7 respective regions which are classified into columns and rows, and the unit was Å.

TABLE 3

| Classification | 1A | 2A | 3A | 4A | 5A | 6A | 7A |
|---|---|---|---|---|---|---|---|
| 1B | 3017.4 | 3017.1 | 3015.4 | 3017.5 | 3022.4 | 3013.3 | 3020.9 |
| 2B | 3019.4 | 3021.2 | 3017.0 | 3013.2 | 3009.4 | 3013.6 | 3022.3 |
| 3B | 3016.2 | 3013.5 | 3012.6 | 3014.7 | 3013.3 | 3006.6 | 3014.6 |
| 4B | 3015.5 | 3014.5 | 3007.6 | 3005.4 | 3008.6 | 3010.6 | 3016.9 |
| 5B | 3019.3 | 3013.6 | 3007.9 | 3015.4 | 3010.6 | 3015.7 | 3015.4 |
| 6B | 3020.2 | 3013.6 | 3016.5 | 3014.9 | 3007.4 | 3013.3 | 3015.1 |
| 7B | 3011.0 | 3016.5 | 3020.1 | 3015.0 | 3014.8 | 3011.7 | 3010.1 |

As shown in Table 4 below, 49 regions of the resist layer fabricated in Example 2 were subjected to thickness measurement. Table 4 refers to FIG. 7, respective regions classified in rows and columns and the unit was Å.

TABLE 4

| Classification | 1A | 2A | 3A | 4A | 5A | 6A | 7A |
|---|---|---|---|---|---|---|---|
| 1B | 3125.5 | 3125.2 | 3133.0 | 3124.7 | 3136.7 | 3125.9 | 3123.0 |
| 2B | 3133.2 | 3126.4 | 3121.8 | 3130.0 | 3126.8 | 3129.2 | 3121.5 |
| 3B | 3129.2 | 3125.4 | 3120.5 | 3129.2 | 3122.3 | 3123.9 | 3127.6 |
| 4B | 3127.1 | 3124.0 | 3120.1 | 3130.2 | 3129.7 | 3125.1 | 3128.1 |
| 5B | 3127.1 | 3123.6 | 3123.6 | 3118.0 | 3127.4 | 3119.2 | 3120.1 |
| 6B | 3126.8 | 3127.1 | 3127.3 | 3124.5 | 3117.5 | 3125.0 | 3124.9 |
| 7B | 3130.3 | 3125.7 | 3128.4 | 3124.2 | 3124.1 | 3126.6 | 3120.4 |

As shown in Table 5 below, 49 regions of the resist layer fabricated in Example 3 were subjected to thickness measurement. Table 5 refers to FIG. 7, respective regions classified in rows and columns and the unit was Å.

TABLE 5

| Classification | 1A | 2A | 3A | 4A | 5A | 6A | 7A |
|---|---|---|---|---|---|---|---|
| 1B | 2867.0 | 2875.7 | 2869.2 | 2870.6 | 2870.2 | 2871.6 | 2871.7 |
| 2B | 2873.5 | 2875.4 | 2867.2 | 2869.0 | 2873.5 | 2869.8 | 2876.0 |
| 3B | 2869.8 | 2872.3 | 2868.3 | 2871.5 | 2867.8 | 2869.5 | 2870.8 |
| 4B | 2872.9 | 2871.6 | 2870.8 | 2877.4 | 2871.4 | 2870.1 | 2871.4 |
| 5B | 2873.3 | 2871.0 | 2868.9 | 2870.4 | 2868.4 | 2870.2 | 2877.3 |
| 6B | 2871.1 | 2871.9 | 2868.0 | 2870.3 | 2872.7 | 2871.9 | 2878.3 |
| 7B | 2872.0 | 2869.1 | 2877.2 | 2869.6 | 2871.4 | 2869.6 | 2871.2 |

As shown in Table 6 below, 49 regions of the resist layer fabricated in Example 4 were subjected to thickness measurement. Table 6 refers to FIG. 7, respective regions classified in rows and columns and the unit was Å.

TABLE 6

| Classification | 1A | 2A | 3A | 4A | 5A | 6A | 7A |
|---|---|---|---|---|---|---|---|
| 1B | 1352.0 | 1348.2 | 1343.8 | 1345.0 | 1342.2 | 1341.2 | 1352.7 |
| 2B | 1349.3 | 1347.5 | 1343.9 | 1344.6 | 1341.6 | 1346.4 | 1343.9 |
| 3B | 1346.9 | 1339.2 | 1341.4 | 1345.5 | 1345.3 | 1341.8 | 1340.2 |
| 4B | 1344.8 | 1343.3 | 1345.4 | 1350.2 | 1343.3 | 1343.5 | 1338.9 |
| 5B | 1343.3 | 1345.5 | 1341.9 | 1344.4 | 1340.1 | 1342.9 | 1340.9 |
| 6B | 1350.1 | 1347.8 | 1346.3 | 1345.3 | 1343.8 | 1343.9 | 1344.6 |
| 7B | 1353.4 | 1346.5 | 1344.9 | 1343.4 | 1342.0 | 1345.0 | 1349.5 |

As shown in Table 7 below, 49 regions of the resist layer fabricated in Example 5 were subjected to thickness measurement. Table 7 refers to FIG. 7, respective regions classified in rows and columns and the unit was Å.

TABLE 7

| Classification | 1A | 2A | 3A | 4A | 5A | 6A | 7A |
|---|---|---|---|---|---|---|---|
| 1B | 1376.1 | 1367.3 | 1362.9 | 1361.5 | 1361.5 | 1366.4 | 1370.1 |
| 2B | 1367.3 | 1365.4 | 1366.5 | 1359.8 | 1360.8 | 1362.9 | 1366.2 |
| 3B | 1366.2 | 1364.1 | 1362.4 | 1367.0 | 1363.1 | 1364.6 | 1362.4 |
| 4B | 1366.0 | 1364.8 | 1367.6 | 1375.9 | 1367.3 | 1360.5 | 1360.9 |
| 5B | 1363.4 | 1359.4 | 1364.3 | 1358.2 | 1362.6 | 1363.4 | 1360.5 |
| 6B | 1372.4 | 1363.5 | 1365.3 | 1371.7 | 1372.5 | 1364.0 | 1367.8 |
| 7B | 1372.8 | 1367.1 | 1371.6 | 1365.2 | 1364.2 | 1366.6 | 1371.0 |

As shown in Table 8 below, 49 regions of the resist layer fabricated in Comparative Example 1 were subjected to thickness measurement. Table 8 refers to FIG. 7, respective regions classified in rows and columns and the unit was Å.

TABLE 8

| Classification | 1A | 2A | 3A | 4A | 5A | 6A | 7A |
|---|---|---|---|---|---|---|---|
| 1B | 3022.2 | 3024.7 | 3016.3 | 3009.8 | 3015.2 | 3020.6 | 3026.4 |
| 2B | 3013.3 | 3012.4 | 3007.1 | 3012.0 | 3007.3 | 3012.1 | 3015.1 |
| 3B | 3011.2 | 3017.5 | 3002.9 | 3005.2 | 2998.9 | 3014.5 | 3010.3 |
| 4B | 3008.4 | 3016.3 | 3009.1 | 3018.5 | 3007.4 | 3011.0 | 3009.9 |
| 5B | 3014.9 | 3014.9 | 3013.1 | 3009.9 | 2998.9 | 3010.1 | 3015.2 |
| 6B | 3017.3 | 3010.6 | 3012.5 | 3007.5 | 3009.4 | 3012.1 | 3013.6 |
| 7B | 3013.4 | 3023.7 | 3012.6 | 3013.1 | 3016.4 | 3014.8 | 3010.6 |

As shown in Table 9 below, 49 regions of the resist layer fabricated in Comparative Example 2 were subjected to thickness measurement. Table 9 refers to FIG. 7, respective regions classified in rows and columns and the unit was Å.

TABLE 9

| Classification | 1A | 2A | 3A | 4A | 5A | 6A | 7A |
|---|---|---|---|---|---|---|---|
| 1B | 3142.2 | 3141.2 | 3156.2 | 3146.4 | 3140.4 | 3142.9 | 3139.4 |
| 2B | 3135.6 | 3140.1 | 3143.6 | 3155.7 | 3149.3 | 3146.5 | 3143.7 |
| 3B | 3136.3 | 3135.7 | 3137.7 | 3165.9 | 3152.8 | 3152.8 | 3140.8 |
| 4B | 3162.5 | 3169.2 | 3151.7 | 3131.5 | 3164.7 | 3156.1 | 3149.6 |
| 5B | 3146.9 | 3150.2 | 3159.7 | 3134.8 | 3128.5 | 3145.0 | 3140.8 |
| 6B | 3141.3 | 3144.6 | 3149.8 | 3150.0 | 3143.1 | 3138.7 | 3136.2 |
| 7B | 3140.7 | 3145.3 | 3148.3 | 3147.3 | 3139.4 | 3137.8 | 3134.5 |

As shown in Table 10 below, 49 regions of the resist layer fabricated in Comparative Example 3 were subjected to thickness measurement. Table 10 refers to FIG. 7, respective regions classified in rows and columns and the unit was Å.

TABLE 10

| Classification | 1A | 2A | 3A | 4A | 5A | 6A | 7A |
|---|---|---|---|---|---|---|---|
| 1B | 1344.6 | 1338.1 | 1334.6 | 1338.3 | 1326.6 | 1335.3 | 1337.9 |
| 2B | 1338.9 | 1342.4 | 1334.6 | 1340.5 | 1336.7 | 1338.1 | 1339.0 |
| 3B | 1336.7 | 1339.2 | 1337.5 | 1320.3 | 1320.0 | 1336.1 | 1329.7 |
| 4B | 1329.6 | 1333.5 | 1329.0 | 1337.4 | 1337.5 | 1337.8 | 1329.8 |
| 5B | 1335.1 | 1335.2 | 1323.0 | 1340.8 | 1337.7 | 1339.2 | 1331.8 |
| 6B | 1338.3 | 1343.3 | 1334.3 | 1337.9 | 1337.2 | 1336.8 | 1338.4 |
| 7B | 1341.9 | 1334.4 | 1334.5 | 1335.9 | 1337.2 | 1336.2 | 1339.5 |

As shown in Table 11 below, 49 regions of the resist layer fabricated in Comparative Example 4 were subjected to thickness measurement. Table 11 refers to FIG. 7, respective regions classified in rows and columns and the unit was Å.

TABLE 11

| Classification | 1A | 2A | 3A | 4A | 5A | 6A | 7A |
|---|---|---|---|---|---|---|---|
| 1B | 1517.9 | 1510.3 | 1507.2 | 1507.1 | 1507.2 | 1508.8 | 1513.4 |
| 2B | 1512.6 | 1515.3 | 1514.4 | 1521.3 | 1516.0 | 1510.6 | 1509.2 |
| 3B | 1505.8 | 1514.0 | 1517.3 | 1521.8 | 1524.5 | 1516.9 | 1506.9 |
| 4B | 1509.9 | 1519.7 | 1519.1 | 1531.0 | 1520.6 | 1512.1 | 1497.4 |
| 5B | 1510.3 | 1515.2 | 1515.4 | 1524.3 | 1523.1 | 1511.9 | 1502.3 |
| 6B | 1510.5 | 1517.9 | 1517.1 | 1517.2 | 1515.6 | 1514.4 | 1507.2 |
| 7B | 1511.9 | 1513.0 | 1510.6 | 1509.4 | 1507.4 | 1507.0 | 1513.4 |

As shown in Table 12 below, the number of optical irregularities in 49 regions of the resist layer fabricated in Example 1 was measured. Table 12 refers to FIG. 7, and respective regions were classified into columns and rows.

TABLE 12

| | | | | | | | |
|---|---|---|---|---|---|---|---|
| Classification | 1A | 2A | 3A | 4A | 5A | 6A | 7A |

| | | | | | | |
|---|---|---|---|---|---|---|
| 1B | 1 | | | | 1 | 1 |
| 2B | 1 | | | | | 2 |
| 3B | 1 | 1 | | 1 | | |
| 4B | | | 2 | | | |
| 5B | | | | | | |
| 6B | | 2 | 1 | | | 2 |
| 7B | 2 | | | | | 1 |

As shown in Table 13 below, the number of optical irregularities in 49 regions of the resist layer fabricated in Example 2 were measured. Table 13 refers to FIG. 7, and respective regions were classified into columns and rows.

TABLE 13

| Classification | 1A | 2A | 3A | 4A | 5A | 6A | 7A |
|---|---|---|---|---|---|---|---|
| 1B | | | | | 1 | 1 | |
| 2B | 1 | | | | | | 1 |
| 3B | 1 | | 1 | | 1 | | |
| 4B | | | | 2 | | 1 | |
| 5B | | | | | 1 | | |
| 6B | | | 2 | 1 | | | 2 |
| 7B | 3 | 1 | | | | | 1 |

As shown in Table 14 below, the number of optical irregularities in 49 regions of the resist layer fabricated in Example 3 were measured. Table 14 refers to FIG. 7, and respective regions were classified into columns and rows.

TABLE 14

| | | | | | | | |
|---|---|---|---|---|---|---|---|
| Classification | 1A | 2A | 3A | 4A | 5A | 6A | 7A |

| | | | | | | |
|---|---|---|---|---|---|---|
| 1B | 2 | | | | 1 | |
| 2B | | | | | | 1 |
| 3B | 1 | 1 | | | | |
| 4B | | | | 1 | 1 | |
| 5B | | | | 1 | | |
| 6B | | | | | | 2 |
| 7B | 1 | | 2 | | | 1 |

As shown in Table 15 below, the number of optical irregularities in 49 regions of the resist layer fabricated in Example 4 were measured. Table 15 refers to FIG. 7, and respective regions were classified into columns and rows.

TABLE 15

| Classification | 1A | 2A | 3A | 4A | 5A | 6A | 7A |
|---|---|---|---|---|---|---|---|
| 1B | | 1 | | | | | 2 |
| 2B | 1 | | | | | | |
| 3B | | | 1 | 1 | | | |
| 4B | | | | 1 | | | |
| 5B | | | | | 1 | | |
| 6B | 1 | | | | | 1 | |
| 7B | | | | | | 1 | |

As shown in Table 16 below, the number of optical irregularities in 49 regions of the resist layer fabricated in Example 5 were measured. Table 16 refers to FIG. 7, and respective regions were classified into columns and rows.

TABLE 16

| | | | | | | | |
|---|---|---|---|---|---|---|---|
| Classification | 1A | 2A | 3A | 4A | 5A | 6A | 7A |

| | | | | | | |
|---|---|---|---|---|---|---|
| 1B | 2 | | | | | 1 |
| 2B | | | | | 1 | |
| 3B | | 2 | | 1 | | |
| 4B | | | | 1 | | |
| 5B | | | 1 | 1 | | 1 |
| 6B | 2 | | | | | 1 |
| 7B | 2 | | | 1 | | |

As shown in Table 17 below, the number of optical irregularities in 49 regions of the resist layer fabricated in Comparative Example 1 were measured. Table 17 refers to FIG. 7, and respective regions were classified into columns and rows.

TABLE 17

| Classification | 1A | 2A | 3A | 4A | 5A | 6A | 7A |
|---|---|---|---|---|---|---|---|
| 1B | 2 | 1 | | 1 | | 2 | |
| 2B | 3 | | | | 1 | 2 | 2 |
| 3B | | | 1 | | | 2 | |
| 4B | | | 2 | | | | |
| 5B | | | | 1 | 1 | | 1 |
| 6B | 3 | | 1 | | | 1 | |
| 7B | 3 | 1 | | | | | 1 |

As shown in Table 18 below, the number of optical irregularities in 49 regions of the resist layer fabricated in Comparative Example 2 were measured. Table 18 refers to FIG. 7, and respective regions were classified into columns and rows.

TABLE 18

| Classification | 1A | 2A | 3A | 4A | 5A | 6A | 7A |
|---|---|---|---|---|---|---|---|
| 1B | | | | 1 | | 2 | 2 |
| 2B | 1 | 1 | | 1 | 1 | 1 | 1 |
| 3B | | | 1 | | 1 | | |
| 4B | | 1 | 1 | | 2 | | |
| 5B | 1 | 1 | | 1 | 1 | | 1 |
| 6B | | 1 | | | | 2 | |
| 7B | 1 | 1 | | 1 | | 2 | |

As shown in Table 19 below, the number of optical irregularities in 49 regions of the resist layer fabricated in Comparative Example 3 were measured. Table 19 refers to FIG. 7, and respective regions were classified into columns and rows.

TABLE 19

| Classification | 1A | 2A | 3A | 4A | 5A | 6A | 7A |
|---|---|---|---|---|---|---|---|
| 1B | 2 | 3 | | 1 | | | 1 |
| 2B | | 2 | 1 | 1 | | 1 | 1 |
| 3B | | | | | 1 | | |
| 4B | | | | | | | |
| 5B | 1 | 1 | 1 | | 1 | | 1 |
| 6B | | 2 | | | | 1 | |
| 7B | 1 | 2 | | | 4 | 2 | 1 |

As shown in Table 20 below, the number of optical irregularities in 49 regions of the resist layer fabricated in Comparative Example 4 were measured. Table 20 refers to FIG. 7, and respective regions were classified into columns and rows.

TABLE 20

| Classification | 1A | 2A | 3A | 4A | 5A | 6A | 7A |
|---|---|---|---|---|---|---|---|
| 1B | | | | 1 | | | 1 |
| 2B | 1 | 1 | | 1 | | 1 | 1 |
| 3B | 1 | | 1 | 2 | | | |
| 4B | | | | | | | |
| 5B | 1 | | | 1 | 1 | | 1 |
| 6B | | 1 | 1 | | | | |
| 7B | 2 | 2 | | 1 | | 3 | 3 |

As shown in Tables 12 to 20, the photoresist layers according to the examples contained a small number of optical irregularities.

### DESCRIPTION OF SYMBOLS

optical substrate 10
light-shielding film 30
photoresist layer 50
flat portion 51
optical irregularities 52 and 53

What is claimed is:

1. A blank mask comprising:
an optical substrate comprising a light-transmitting substrate and a light-shielding film disposed on the light-transmitting substrate; and
a photoresist layer disposed on the optical substrate,
wherein the photoresist layer comprises 49 regions that are divided into 7 regions arranged at regular intervals in a horizontal direction and 7 regions arranged at regular intervals in a vertical direction,
wherein the 49 regions comprise:
a first region corresponding to a center of the optical substrate;
second regions arranged along a periphery of the first region;
third regions arranged along a periphery of the second regions; and
fourth regions corresponding to an outer edge of the optical substrate,
wherein a density of optical irregularities in the fourth regions is greater than a density of optical irregularities in the first region, the second regions and the third regions.

2. The blank mask according to claim 1, wherein the optical irregularities are detected by a 532 nm laser and are arranged in a number of less than 30/36 inches² on the light-shielding film.

3. The blank mask according to claim 1, wherein a density of optical irregularities in the fourth region is 15/36 inches² to 25/36 inches².

4. The blank mask according to claim 3, wherein a density of optical irregularities in the first region, the second region and the third region is 5/36 inches² to 20/36 inches².

5. The blank mask according to claim 1, wherein a diameter of the optical irregularities is 10 nm to 500 nm.

6. The blank mask according to claim 1, wherein a difference between the density of optical irregularities in the fourth region and the density of optical irregularities in the first region, the second region and the third region is 1/36 inches² to 15/36 inches².

7. The blank mask according to claim 1, wherein, in each of the fourth regions, optical irregularities are 3 or less.

8. The blank mask according to claim 1, wherein the photoresist layer comprises a flat portion disposed on the light transmission part, and
the optical irregularities have optical thicknesses different from the light transmission part.

9. The blank mask according to claim 8, wherein the optical irregularities comprise an optical path-changing part.

10. The blank mask according to claim 9, wherein the optical path-changing part has a refractive index different from the flat portion.

11. A blank mask comprising:
a light-transmissive substrate;
a light-shielding film disposed on the light-transmissive substrate; and
a photoresist layer disposed on the light-shielding film,
wherein the photoresist layer comprises 49 regions that are divided into 7 regions arranged at regular intervals in a horizontal direction and 7 regions arranged at regular intervals in a vertical direction,
wherein a thickness variation in the 49 regions is less than 100 Å.

12. The blank mask according to claim 11, wherein the 49 regions comprise:
a first region corresponding to a center of the optical substrate;
second regions arranged along a periphery of the first region;
third regions arranged along a periphery of the second regions; and
fourth regions corresponding to an outer edge of the optical substrate,
wherein an average thickness of the fourth regions is thicker than an average thickness of the third regions.

13. The blank mask according to claim 12, wherein the average thickness of the fourth regions is about 3 Å to about 10 Å thicker than the average thickness of the third regions.

14. The blank mask according to claim 12, wherein the average thickness of the fourth regions is thicker than an average thickness of the second regions.

15. The blank mask according to claim 12, wherein an average thickness of the first region is thicker than an average thickness of the second regions.

16. The blank mask according to claim 12, wherein an average thickness of the first region is thicker than the average thickness of the third regions.

17. A method of fabricating a blank mask, the method comprising:
forming an optical substrate comprising a light-shielding film on a transparent substrate; and
forming a photoresist layer on the light-shielding film while rotating the optical substrate,
wherein forming the photoresist layer comprises:
performing first rotation for the optical substrate;
performing second rotation for the optical substrate at a speed faster than the first rotation;
performing third rotation for the optical substrate at a speed faster than the second rotation;
performing fourth rotation for the optical substrate at a speed faster than the third rotation;
performing fifth rotation for the optical substrate at a slower speed than fourth rotation; and
performing sixth rotation for the optical substrate at a slower speed than the fifth rotation.

18. The method according to claim 17, wherein the first rotation speed is 30 rpm to 70 rpm,
the second rotation speed is 50 rpm to 100 rpm,
the third rotation speed is 70 rpm to 150 rpm,
the fourth rotation speed is 800 rpm to 3000 rpm,
the fifth rotation speed is 500 rpm to 2500 rpm, and
the sixth rotation speed is 100 rpm to 500 rpm.

19. The method according to claim 17, wherein the first rotation operation, the second rotation operation, the third rotation operation, the fourth rotation operation, the fifth rotation operation and the sixth rotation operation are performed at 20° C. to 30° C.

20. The method according to claim 17, wherein the fourth rotation operation is performed for 0.5 sec to 2 sec.
